(19) United States
(12) Patent Application Publication
(10) Pub. No.: US 2020/0105957 A1
(43) Pub. Date: Apr. 2, 2020

(54) PHOTODIODE HAVING LIGHT REDIRECTION LAYER

(71) Applicant: Hewlett Packard Enterprise Development LP, Houston, TX (US)

(72) Inventors: Sagi Mathai, Sunnyvale, CA (US); Wayne Victor Sorin, Mountain View, CA (US); Michael Renne Ty Tan, Menlo Park, CA (US)

(21) Appl. No.: 16/147,507

(22) Filed: Sep. 28, 2018

(51) Int. Cl. H01L 31/102; H01L 31/054; H01L 31/0232; H01L 31/0216; G02B 6/12

(52) U.S. Cl. CPC H01L 31/102; H01L 31/054; G02B 2006/12107; H01L 31/02161; G02B 6/12; H01L 31/02327

(57) ABSTRACT

A substrate-entry photodiode includes a light redirection layer over an absorbing layer of the photodiode. The light redirection layer may reflect light back through the absorbing layer of the photodiode at an oblique angle. The oblique angle prevents the reflected light from exiting the substrate entry aperture while providing a second pass through the absorbing layer.

### BACKGROUND

A photodiode is a semiconductor device that converts light into an electrical current. A substrate entry photodiode receives light through the device substrate. In substrate entry photodiodes, thin photodiode absorbing layers lead to higher speed due to shorter transit time for photogenerated electron-hole pairs, but at the expense of responsivity and return loss. In low loss optical links, back reflections will reach laser transmitters and increase their relative intensity noise (RIN). Noise is a limiting factor in achieving low bit error rate, especially when complex modulation schemes such as PAM-4 are employed. Common methods to prevent reflections from increasing the laser RIN include adding an optical isolator at the transmitter and attenuation along the link, but these solutions increase cost, complexity and degrade signal to noise ratio, and therefore bit error rate.

### BRIEF DESCRIPTION OF THE DRAWINGS

Certain examples are described in the following detailed description and in reference to the drawings, in which:

FIG. 1A illustrates a substrate entry photodiode;

FIG. 1B illustrates a close up view of the heterojunction at the upper contact of the photodiode;

FIG. 2A illustrates an example photodiode included a blazed grating redirection layer and an internal antireflection layer;

FIG. 2B illustrates a top-down view of the blazed grating redirection layer of FIG. 2A;

FIG. 3 illustrates an example photodiode comprising a diffusive reflector light redirection layer;

FIG. 4 illustrates an example photodiode including a light redirection layer;

FIG. 5 illustrates an example method of manufacturing a photodiode including a light redirection layer; and

FIG. 6 illustrates an example method of operation of a photodiode including a light redirection layer.

### DETAILED DESCRIPTION OF SPECIFIC EXAMPLES

Implementations of the described technology provide a photodiode design to simultaneously minimize back reflections and increase responsivity by eliminating unwanted reflections at heterojunctions in the photodiode material and metal surfaces, and adding light scattering structures to redirect unabsorbed light into the plane of the absorbing layer.

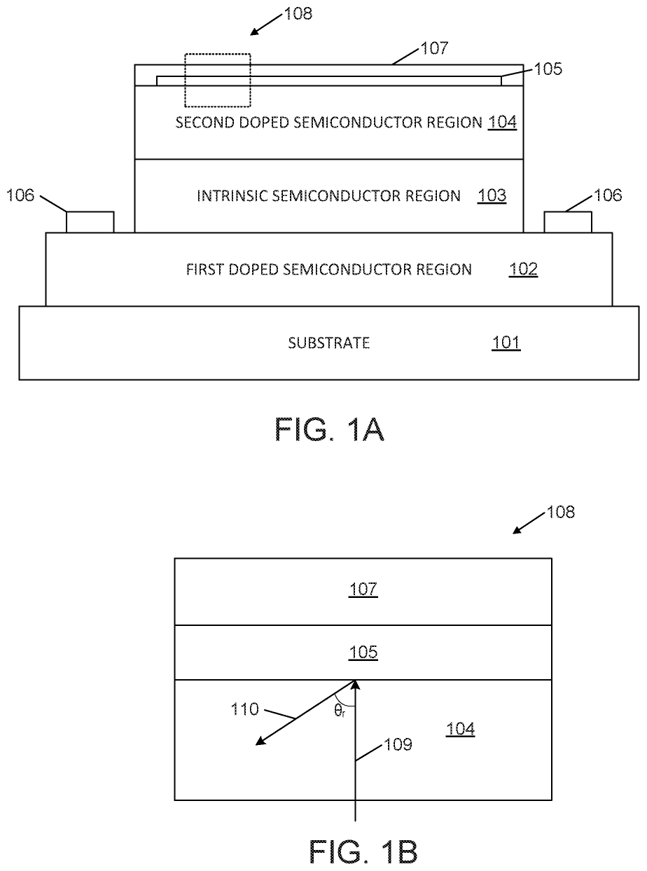

FIG. 1A illustrates a substrate entry photodiode. FIG. 1B illustrates a close up view of the heterojunction at the upper contact of the photodiode. For example, the photodiode may be a photodetector used in an optical communication system.

The photodiode includes a substrate 101. The substrate 101 is the entry point for incident light on the photodiode. The photodiode may be a surface-normal illuminated detector, where incident light is perpendicular to the plane of the substrate 101. However, in practice, some input light may be incident on the substrate 101 at non-perpendicular angles. In alternate embodiments, the incident light on the substrate 101 may be intentionally at a non-perpendicular angle. In some implementations the substrate 101 may include structures such as integrated lenses. Additionally, the lower surface of the substrate may include coatings such as antireflective coatings. The substrate 101 may be a semiconductor material conducive to the formation of the photodiode thereon. The substrate 101 may be an indirect or a direct bandgap semiconductor. For example, the substrate 101 may be composed of a material such as indium phosphide (InP), silicon, or gallium arsenide.

The photodiode further includes a first semiconductor region 102 over the substrate 101. For example, in a PIN photodiode, the first semiconductor region 102 may be a heavily n+ doped layer of semiconductor material. In a NIP photodiode, the first semiconductor region 102 may be a heavily p+ doped layer of semiconductor material. The region 102 may have different compositions in different implementations. For example, the region 102 may be a doped region of the substrate, or a separate layer deposited onto the substrate. The region 102 may be composed of any material suitable for use in a substrate entry photodiode. In one example, the region 102 is composed of n+ doped InP.

The photodiode further comprises an intrinsic semiconductor region 103. The intrinsic region 103 may comprise the primary absorbing layer of the photodetector. The intrinsic region 103 may comprise an undoped semiconductor material, or a semiconductor material doped with equal n-type and p-type dopants. In some cases, the intrinsic region 103 may comprise a semiconductor material having a resistance that is substantially greater than that of the other two semiconductor regions 102, 104. In some implementations, the intrinsic region 103 is composed of a different material type than the first region 102. For example, the first region may be an InP material and the intrinsic region 103 may comprise indium gallium arsenide (InGaAs). In other examples, the intrinsic region 103 may comprise other materials from other systems, such as, but not limited to, InP, gallium arsenide (GaAs), gallium phosphide (GaP), indium gallium phosphide (InGaP), indium aluminum arsenide (InAlAs), indium gallium arsenide phosphide (InGaAsP), indium aluminum gallium arsenide (InAlGaAs), germanium (Ge), silicon (Si), or silicon-germanium (SiGe).

The photodiode further comprises a second doped semiconductor region 104 over the intrinsic region 104. In a PIN photodiode, the second semiconductor region 104 may be a heavily p+ doped layer of semiconductor material. In a NIP photodiode, the second doped semiconductor region may be a heavily n+ doped layer of semiconductor material. The region 104 may have different compositions in different implementations and may be composed of any material suitable for use in a substrate entry photodiode. In some implementations, the second doped semiconductor region 104 is comprised of a material from the same system as the intrinsic layer. For example, the intrinsic semiconductor region 103 may comprise a layer of undoped InGaAs and the second doped semiconductor region 104 may comprise a layer of p+ (or n+) doped InGaAs. In other examples, the second region 104 may comprise other materials from other systems, such as, but not limited to, InP, GaAs, GaP, InGaP, InGaAsP, InAlAs, InAlGaAs, Ge, Si, or SiGe.

The photodiode further comprises a first metal contact 106 electrically coupled to the first doped semiconductor region. In the illustrated example, the intrinsic region 103 and the second doped region 104 have a smaller diameter than the first doped semiconductor region, forming a mesa structure upon the first doped semiconductor region. In this implementation, the first metal contact 106 comprises a ring that is disposed on the upper surface of the first region 102 in the annulus defined by the first region's 102 outer diameter and the mesa's outer diameter. The first metal contact 106 may comprise an alloyed ohmic contact material such as gold, germanium, nickel, gold.

The photodiode further comprises a second metal contact 107 electrically coupled to the second doped semiconductor region. In the illustrated example, the contact 107 is disposed over the entire mesa structure (i.e., over the entire upper surface of the second region 104). Other implementations may utilize other geometries. For example, the metal contact 107 may be a ring on the perimeter of the upper mesa surface. The second metal contact 107 may be composed of an ohmic contact material such as titanium, platinum, gold. The first and the second contacts 106, 107 may be composed of the same metals, and in one example comprise gold.

The photodiode further comprises a light redirection layer 105 over the second doped semiconductor region 104. In the illustrated example, the light redirection layer is between the second metal contact 107 and the second doped semiconductor region 104. In the illustrated example, the light redirection layer 107 has a smaller diameter than the second contact 107 such that the second contact 107 contacts the second region 104 at its periphery. For example, the illustrated geometry may be employed if the light redirection layer is composed of an insulating material such as silicon dioxide (SiO₂), or if there are insulating layers above or below the light redirection layer, or if there are semiconductor layers above or below the light redirection layer. In other implementations, the light redirection layer 105 extends to the edge of the mesa and the second contact's 107 electrical coupling to the second region 104 occurs through the light redirection layer 105. For example, in these implementations, the light redirection layer 105 may be a portion of the metal contact 107 or the second region 104. For example, the light redirection layer 105 may be surface relief on the second metal contact 107.

The light redirection layer 105 reflects incident light at an oblique angle. FIG. 1B illustrates region 108 in closer detail to illustrate the operation of the light redirection layer 105. Incident light 109 enters the photodiode perpendicular to the substrate and the second metal contact. Light 109 that is not absorbed in the first pass through the regions 103 impinges on the redirection layer 105 and reflected at a non-perpendicular angle. The redirection layer 105 may be a specular reflector that reflects the light 109 at an oblique angle θᵣ. For example, the redirection layer 105 may comprise angled reflective surfaces, convex mirrors, or specular reflection gratings such as blazed gratings. The redirection layer 105 may be diffusive reflector such that the impinging light 109 may be reflected through a range of angles. For example, the redirection layer 105 may comprise randomly located and sized structures such as surface roughness, or diffusive reflection gratings.

The redirected light 110 may be angled to pass through the second doped semiconductor region 104 and at least a portion of the intrinsic semiconductor region. This creates a second pass for light (that was not absorbed in the first pass) through the intrinsic region 103 without allowing light to exit the entry region of the substrate. This improves the return loss of the photodiode by preventing at least a portion of the back reflection that would otherwise occur, while improving responsivity by providing a second pass through the absorption region.

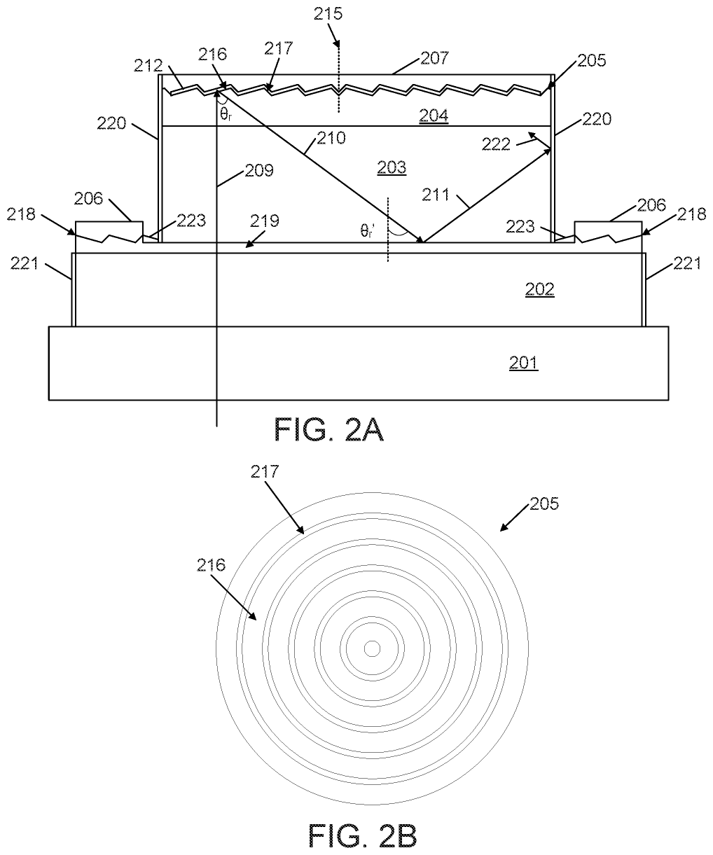

FIG. 2A illustrates an example photodiode including a blazed grating redirection layer 205 and an internal antireflection layer 219.

The illustrated photodiode includes a substrate 201, a first doped semiconductor region 202, an intrinsic semiconductor region 203, a second doped semiconductor region 204, and two metal contacts 206, 207. These elements may be as described with respect to the substrate 101, first doped semiconductor region 102, intrinsic semiconductors region 103, second doped semiconductor region 104, and metal contacts 106, 107 of FIG. 1A, respectively.

The photodiode further comprises an antireflection layer 219. In the illustrated example, the antireflection layer 219 is disposed between the first doped semiconductor region and the intrinsic semiconductor region. The antireflection layer 219 may reduce back reflections that would otherwise occur at the boundary between regions 202 and 203. For example, the antireflection layer 219 may comprise a material having an index of refraction between that of the first region 202 and the intrinsic region 203.

In some implementations, the antireflection layer 219 is composed of a different semiconductor material than that of the first region 202 or the intrinsic region 203. For example, in a system having an n+ InP first region and an InGaAs intrinsic region 203, the antireflection layer 219 may be composed of InGaAsP. The amounts of In, Ga, As, and P may be selected according to the desired index of refraction. In some implementations, the composition of the antireflection layer 219 may vary from the bottom of the layer to the top of the layer. For example, the antireflection layer 219 may have a height dependent index of refraction that varies as a gradient from the index of refraction of region 202 at its bottom to the index of refraction of the intrinsic region 203 at its top. For example, the composition of the layer 219 may vary in a height-dependent fashion to provide the index of refraction gradient.

In other implementations, the antireflection layer 219 is composed of a material from the same material system as that of the first region 202 or the intrinsic region 203. The specific atomic ratios of the antireflection layer may be selected to provide an index of refraction for the antireflection layer 219 that is between those of the first region 202 and the intrinsic region 203. For example, the intrinsic region 203 may be composed of a first InGaAsP alloy and the antireflection layer 219 may be composed of a second InGaAsP alloy.

In the illustrated example, the antireflection layer 219 extends to the periphery of the region 202 and the first metal contact 206 is disposed on the antireflection layer 219. In this example, the antireflection layer 219 is composed a material that does not interfere with the electrical coupling between the region 202 and the contact 206. For example, the antireflection layer 219 may be doped with the same type of dopant as the region 202. In other examples, the antireflection layer 219 may end at the periphery of the intrinsic region 203, or may be contained within the perimeter of intrinsic region 203.

In the illustrated example, the antireflection layer 219 is present in the area between the inner surface of the contact 206 and the outer wall fo the intrinsic region 203. Air interfaces between a semiconductor and air may have a certain degree of reflectivity (e.g. on the order of 30% reflectivity), which may be reduced or eliminated using layer 219.

In some implementations, additional reflective layers 220, 221 are disposed at one or more air interfaces of the photodiode. For example, the layers 220, 221 may comprise single or multilayer dielectric coatings. In the illustrated example, coating 220 comprises a specular reflector. The reflector reflects the internally reflected light 211 back through the layers 203, 204 as third reflected light 222. This may improve the responsivity of the photodiode by providing another pass through the absorbing layer. In the illustrated example, the reflector 220 is a planar reflector. However, in other examples, the layer 220 may have a configuration as described with respect to the light redirection layer described herein. If present, the layer 221 may comprise the same type as layer 220, or may be a different type. For example, the layer 221 may be an anti-reflection coating to reduce the reflectivity between the semiconductor 202 and air. As another example, the layer 221 may have a first light redirection profile while the layer 220 has a second light redirection profile.

The photodiode further comprises a light redirection layer 205. In this example, the light redirection layer comprises a specular reflector that reflects incident light 209 that is perpendicular to the second metal contact 207 at a non-perpendicular angle θᵣ. Here, θᵣ is such that the reflected light 210 undergoes total internal reflection at a boundary within the photodiode. In the illustrated example, refraction does not occur between regions 204 and 203, so 74 ᵣ is greater than or equal to the critical angle for total internal reflection at the lower boundary of 203. In other examples, refraction may occur at interfaces within the diode, such as the interface between region 204 and 203. In these examples, θᵣ being such that the reflected light 210 undergoes total internal reflection at the lower boundary after refraction at one or more interfaces within the diode. In the illustrated example, the total internal reflection occurs at the lower boundary of the intrinsic layer 203. This allows light that is unabsorbed within the second pass through the intrinsic layer 203 to have a third pass through the intrinsic layer 203, further increasing responsivity of the photodiode. In other implementations, the total internal reflection may occur at the lower boundary of the antireflection layer 219 (if one is present), or at the lower boundary of the first doped region 202.

In this example, the light redirection layer 205 comprises a surface relief on the lower boundary of the upper metal contact 207. In various implementations, the layer 205 may have various geometries. For example, the layer 205 may comprise a plurality of annular structures having a convex curved or concave curved profiles. In the illustrated example, the layer 205 has a blazed cross section, comprising a plurality of triangular or saw-toothed structures. The structures have a long face 216 and a short face 217. The light 209 reflects off of the long faces 216 at the angle of reflection θᵣ. Light reflecting off of the short faces 217 will be at an angle θᵣ′, where θᵣ′ >θᵣ. Accordingly, if θᵣ is greater than the critical angle for total internal reflection at a boundary within the photodiode, then θᵣ′ will also be greater than the critical angle. In this example, the each long face of the structures 216 faces towards the center line 215 of the diode. A majority of the first pass unabsorbed light 209 will reflect off one of the longer faces 216 and will thereby be reflected towards and through the centerline 215. This increases the total path length for a majority of the reflected light 210, 211 compared to an implementation having isosceles structures.

In the illustrated example, the structures are annular and are centered at the central axis 215. Accordingly, the blazed grating illustrated in FIG. 2A comprises a plurality of concentric ring. This arrangement is illustrated in FIG. 2B. As illustrated in FIG. 2A, each ring has a triangular cross section. In other examples, the structures may comprise rectilinear parallel rulings or structures having three or more facets, such as pyramids.

In the illustrated example, the light redirection layer 205 further comprises a reflectivity enhancement layer 212 between the upper boundary of the region 204 and the lower boundary of the metal contact 207. The reflectivity enhancement layer 212 increases the reflectivity at the boundary between the region 204 and the contact 207. For example, the reflectivity enhancement layer 212 may comprise a layer of silicon dioxide having a thickness approximately ¼ of a wavelength that the photodiode is designed to detect. In this example, the enhancement layer 212 extends under a portion of the contact 207, but ends within the perimeter, allowing electrical coupling between the contact 207 and region 204 at the periphery of the mesa.

The illustrated example further comprises a second light redirection layer 218 between the first region 202 and the first metal contact 206. For example, second light redirection layer 218 may comprise a surface relief structure on the lower boundary of the contact 206. In the illustrated example, the second light redirection layer 218 has the same geometry of the first redirection layer 205. However, in other implementations, the second redirection layer 218 may have a different configuration. For example, the second redirection layer 218 may be a diffusive reflector while the first redirection layer 205 is a specular reflector, or vice versa.

In some implementations, light redirection layer 223 is present between the inner wall of the contact 206 and the outer wall of the intrinsic layer 203. In the illustrated example, light redirection layer 223 is present in addition to antireflection layer 219. In other examples, the light redirection layer 223 may be present instead of the layer 219. For example, the light redirection layer 223 may be an extension of the light redirection layer 218. In other examples, the light redirection layer 218 may have a different configuration. For example, the light redirection layer 218 may be a blazed grating while the light redirection layer 223 may be surface roughening on the upper surface of the layer 219. As another example, the redirection layer 223 may be a diffusive reflector while the redirection layer 218 is a specular reflector, or vice versa.

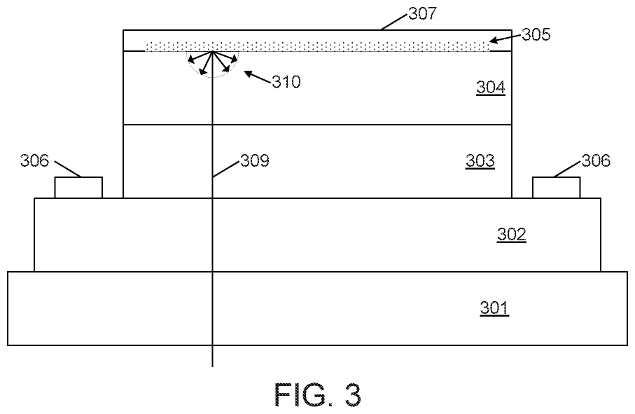

FIG. 3 illustrates an example photodiode comprising a diffusive reflector light redirection layer. The example photodiode comprises a substrate 301, a first doped semiconductor region 302, an intrinsic region 303, a second doped semiconductor region 304 and a pair of contacts 307, 306. These elements may be as described with respect to substrate 101, first doped semiconductor region 102, intrinsic region 103, second doped semiconductor region 104 and contacts 107, 106 of FIG. 1A, respectively.

In this example, the light redirection layer 305 comprises a diffusive reflector. Incoming light 309 that is not absorbed in its first pass through the photodiode is scattered off of the layer 305 in a range of reflection 310. In the illustrated example, the redirection layer 305 comprises a Lambertian reflector with a hemispherical range 310 of reflection. For example, the layer 305 may comprise a plurality of random structures, such as surface roughness. In other examples, the redirection layer 305 may have a tuned range or reflection. For example, the redirection layer 305 may comprise a grating having a tuned reflection profile.

In other implementations, the photodiode may include other layers, such as an antireflection layer between the first region 302 and the intrinsic region 303, as described with respect to FIG. 2A. Additionally, a second redirection layer may be disposed between the contact 306 and the first semiconductor region 302. Additionally, the redirection layer 305 may comprise a reflectivity enhancement layer as described with respect to FIG. 2A. For example, the surface relief structures may be present on the lower boundary of such a reflectivity enhancement layer.

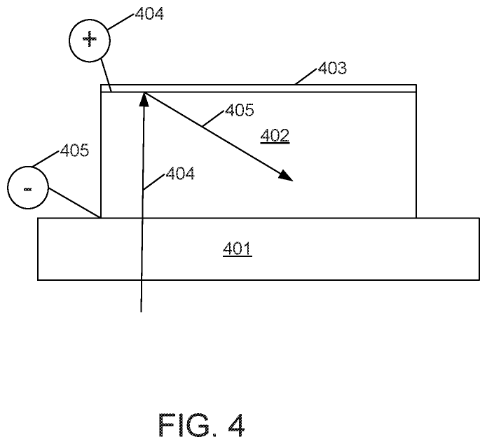

As described above, an internal light redirection layer may be included in various types of photodiodes. FIG. 4 illustrates a photodiode including a light redirection layer 403. The photodiode includes a substrate 401, a photodiode body 402 including layer 403 and contacts 404, 405. For example, the photodiode may comprise an avalanche photodiode, where the body 402 comprises a plurality of doped and undoped semiconductor layers including a carrier multiplication layer. As another example, the photodiode may comprise a metal-semiconductor-metal (MSM) photodiode, a uni-traveling carrier photodiode, or other type of photodiode. In the illustrated example, the photodiode body 402 is disposed as a mesa on the substrate 401. However, in other examples, the photodiode body 402 may be co-planar with the substrate 401. The body 402 further includes a light redirection layer 403. The light redirection layer 403 may be as described with respect to light redirection layers 105, 205, or 305 of FIGS. 1A, 1B, 2A, 2B, or 3, respectively. The light redirection layer reflects incident light 404 at an oblique angle to produce redirected light 405. In implementations where contact 404 is a layer over the photodiode body, the light redirection layer 403 may be present at the interface between the body 402 and the contact 404. For example, the layer 403 may comprise at the interface of the body 402 and the contact 404. In other examples, the contact 404 may have a different configuration such that it does not cover the body 402. In these examples, the layer 404 may comprise surface structures etched into the upper interface of the body 402, material coatings, or a combination thereof.

The photodiode may comprise other features as discussed above. For example, the body 402 may comprise one or more internal anti-reflection layers. For example, the anti-reflection layers may be as described with antireflection layer 219 of FIG. 2A. As another example, the photodiode may comprise high and low reflection layers or coating at one or more air interfaces of the body 402. For example, such layers may be as described with respect to layers 220 and 221 of FIG. 2A, respectively. Additionally, there may be a second light redirection layer between the contact 405 and the body 402. The second light redirection layer may be as described with respect to layer 218 of FIG. 2A. For example, a second light redirection layer may be present in implementations where the contact 405 is disposed on a horizontal surface of the body 402, such as in an implementation utilizing a stepped mesa body 401, such as FIGS. 1A-3,

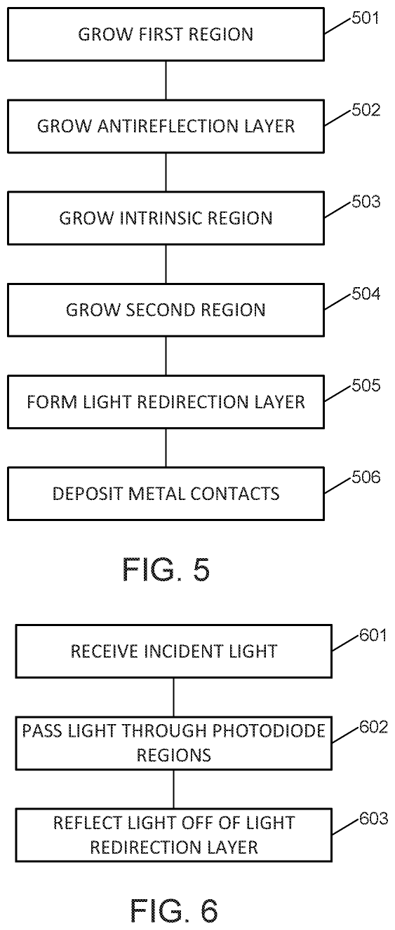

FIG. 5 illustrates an example method of manufacturing a photodiode including a light redirection layer. For example, the illustrated method may be used to manufacture a photodiode of the type described above.

The method includes block 501. Block 501 comprises growing a first doped semiconductor region over a substrate. For example, the substrate and the first doped semiconductor region may be as described above with respect to substrate 101 and first doped semiconductor region 102 of FIG. 1. In some examples, block 501 may comprise epitaxially growing the first doped semiconductor region on the substrate.

In an implementation utilizing an internal antireflection layer, the method may include block 502. In implementations without an internal antireflection layer, block 502 may be omitted. Block 502 comprises growing an antireflection layer over the first doped semiconductor region. The antireflection layer may be as described with respect to antireflection layer 219 of FIG. 2A. For example, block 502 may comprise epitaxially growing the antireflection layer on the first doped semiconductor region. As another example, block 502 may comprise varying the composition of the growth medium of the first region or beginning to grow an intrinsic region with a varied composition to provide a region of varied index of refraction. For example, block 502 may comprise beginning to grow an intrinsic region with an index of refraction changing as a gradient with the height of the antireflection layer.

The example method further includes block 503. Block 503 comprises growing an intrinsic semiconductor region over the first doped semiconductor region. For example, the intrinsic semiconductor region may be as described with respect to the intrinsic semiconductor regions 103, 203, and 303. If the photodiode include an antireflection layer, block 503 may comprise epitaxially growing the intrinsic semiconductor on the antireflection layer. If the photodiode does not include an antireflection layer, block 503 may comprise growing the intrinsic region on the first semiconductor region.

The example method further includes block 504. Block 504 comprises growing a second doped semiconductor region over the intrinsic semiconductor region. For example, the second doped semiconductor region may be as described with respect to regions 104, 204, or 303 of FIGS. 1A, 2A, and 3, respectively. In some implementations, block 504 comprises epitaxially growing the second doped semiconductor region on the intrinsic semiconductor region.

The example method further includes block 505. Block 505 comprises forming a light redirection layer over the second doped region. For example, the light redirection layer may be as described with light redirection layers 105, 205, or 305 of FIGS. 1A-B, 2A-B, or 3, respectively.

In some implementations, block 505 includes etching a plurality of structures for the light redirection layer into the second doped semiconductor region before depositing the light redirection layer. Block 505 may comprise etching the inverse of the lower boundary of the light redirection layer into the upper surface of the second doped semiconductor region. For example, block 505 may comprise etching a plurality of concentric ring-shaped triangular valleys into the upper surface of the second doped semiconductor region. As other examples, block 505 may comprise etching concavities for a convex mirror light redirection layer, or etching the inverse of a grating to be used for a grating light redirection layer. As another example, block 505 may comprise roughening the surface of the second semiconductor region for a diffusive or scattering light redirection layer.

In implementations using a reflection enhancement layer between the second doped semiconductor region and the upper metal contact, block 505 may comprise depositing the material of the reflection enhancement layer on the etched surface of the second doped semiconductor region. If the reflection enhancement layer is composed of an insulating material such as silicon dioxide, this may include masking off a portion of the periphery of the second doped region to provide an area to allow the second contact to electrically couple to the second doped region.

In implementations where the light redirection layer comprises surface relief structures on the lower boundary of the metal contact, block 505 may include beginning to deposit the metal for the metal contact over the second doped semiconductor region. For example, block 505 may comprise depositing the metal into the etched structures formed on the second doped semiconductor region with metal such as titanium, platinum, gold.

In some implementations, block 505 may further include forming a second light redirection layer over the first doped semiconductor region. For example, the second light redirection layer may be as described with respect to the second light redirection layer 218 of FIG. 2. In these implementations, block 505 may include etching the inverse of the second light redirection layer into the region of the upper surface of the first doped semiconductor region in which the lower metal contact will be deposited. In implementations employing an antireflection layer that extends to the periphery of the first doped region, block 505 may include etching the inverse of the layer into the upper surface of the antireflection layer.

The method further includes block 506. Block 506 comprises depositing a first metal contact electrically coupled to the first doped semiconductor region and depositing a second metal contact electrically coupled to the second doped semiconductor region. For example, the first metal contact may comprise a metal contact as described with respect to contacts 106, 206, or 306 of FIGS. 1A, 2A, and 3, respectively. The second metal contact may comprise a metal contact as described with respect to contacts 107, 207, or 307 of FIGS. 1A and 1B, 2A, and 3, respectively. In an implementation utilizing a second light redirection layer that comprises surface reliefs, block 506 may comprise continuing to deposit the metal to create the contacts.

FIG. 6 illustrates an example method of operation of a photodiode including a light redirection layer. For example, any of the photodiodes described herein may be operated as illustrated in this method.

FIG. 5 includes block 601. Block 601 comprises receiving incident light at a substrate of a photodiode, the incident light being perpendicular to the substrate.

Block 602 comprises passing the light through a first doped semiconductor region over the substrate, an intrinsic semiconductor region over the first doped semiconductor region, and a second doped semiconductor region over the intrinsic semiconductor region. For example, first doped semiconductor region, the intrinsic semiconductor region, and the second doped semiconductor region may be described with respect to the first doped semiconductor regions 102, 202, 302, the intrinsic semiconductor regions 103, 203, 303, and the second doped semiconductor region 104, 204, 304 of FIGS. 1A, 2A, and 3, respectively.

Block 603 comprises reflecting the light off of a light redirection layer over the second doped semiconductor region at an oblique angle. In some cases, block 603 may comprise reflecting the light off of a specular reflector at an oblique angle. For example, block 603 may comprise reflecting the light off of a blazed grating. In some cases, block 603 may comprise reflecting the light off at an oblique angle greater than or equal to a critical angle for total internal reflection within the photodiode.

In other cases, block 603 may comprise reflecting the light at a plurality of oblique angles. For example, block 603 may comprise reflecting the light off of a diffusive reflector such as a roughened interface between the second doped semiconductor region and an upper metal contact.

As used herein, terms indicating directionality are used in a frame of reference where the substrate is the lowest layer, as illustrated in FIG. 1A, for example. The term “over” means above but not necessarily contacting. Similarly, under means below but not necessarily contacting. The term “on” means contacting or contiguous with.

In the foregoing description, numerous details are set forth to provide an understanding of the subject disclosed herein. However, implementations may be practiced without some or all of these details. Other implementations may include modifications and variations from the details discussed above. It is intended that the appended claims cover such modifications and variations.

1. A photodiode, comprising:
a substrate;
a photodiode body over the substrate, the photodiode body comprising a light redirection layer.

2. The photodiode of claim 1, wherein the photodiode body further comprises:
a first doped semiconductor region over the substrate;
an intrinsic semiconductor region over the first doped semiconductor region;
a second doped semiconductor region over the intrinsic semiconductor region; and
the light redirection layer over the second doped semiconductor region; and
the photodiode further comprises:
a first metal contact electrically coupled to the first doped semiconductor region; and
a second metal contact electrically coupled to the second doped semiconductor region.

3. The photodiode of claim 2, wherein the light redirection layer is between the second metal contact and the second doped semiconductor region.

4. The photodiode of claim 12, wherein the light redirection layer comprises a specular reflector that reflects incident light that is perpendicular to the second metal contact at a non-perpendicular angle.

5. The photodiode of claim 4, wherein the non-perpendicular angle is such that reflected light undergoes total internal reflection within the photodiode.

6. The photodiode of claim 1, wherein the light redirection layer comprises a diffusive reflector.1, wherein the light redirection layer comprises a diffusive reflector.

7. The photodiode of claim 2, wherein the light redirection layer comprises a roughened surface of the second doped semiconductor region or the second metal contact.

8. The photodiode of claim 2, wherein the light redirection layer comprises a surface relief on the second doped semiconductor region or the second metal contact.

9. The photodiode of claim 8, wherein the surface relief comprises a blazed reflection grating.

10. The photodiode of claim 2, further comprising a second light redirection layer between the first doped semiconductor region and the first metal contact.

11. The photodiode of claim 9, wherein the blazed reflection grating comprises a plurality of concentric rings, each ring having a triangular cross section.

12. The photodiode of claim 4, further comprising an antireflection layer between the first doped semiconductor region and the intrinsic semiconductor region.

13. The photodiode of claim 1, further comprising a reflecting layer disposed on the side of the photodiode body.

14. A method comprising:
growing a first doped semiconductor region over a substrate;
growing an intrinsic semiconductor region over the first doped semiconductor region;
growing a second doped semiconductor region over the intrinsic semiconductor region;
forming a light redirection layer over the second doped semiconductor region;
depositing a first metal contact electrically coupled to the first doped semiconductor region; and
depositing a second metal contact electrically coupled to the second doped semiconductor region.

15. The method of claim 14, further comprising:
etching a plurality of structures for the light redirection layer into the second doped semiconductor region before depositing the light redirection layer.

16. The method of claim 15, wherein depositing the light redirection layer comprises depositing the metal of the second metal contact into the plurality of structures.

17. The method of claim 15, wherein the plurality of structures comprise roughened surface features.

18. The method of claim 15, wherein the plurality of structures comprise a plurality of concentric rings, each ring having a triangular cross section.

19. The method of claim 14, further comprising growing an antireflection layer over the first doped semiconductor region before growing the intrinsic semiconductor region over the first doped semiconductor region.

20. A method comprising:
receiving incident light at a substrate of a photodiode, the incident light being perpendicular to the substrate;
passing the light through a first doped semiconductor region over the substrate, an intrinsic semiconductor region over the first doped semiconductor region, and a second doped semiconductor region over the intrinsic semiconductor region; and
reflecting the light off of a light redirection layer over the second doped semiconductor region at an oblique angle.

21. The method of claim 20, further comprising reflecting the light off of the light redirection layer by scattering the light at a plurality of angles.

22. The method of claim 20, wherein the light redirection layer comprises a blazed grating.
